(19) United States
(12) Patent Application Publication
(10) Pub. No.: US 2013/0247815 A1
(43) Pub. Date: Sep. 26, 2013

(54) SINGLE CRYSTAL PRODUCTION APPARATUS AND METHOD FOR PRODUCING SINGLE CRYSTAL

(71) Applicants: Kosei Sugawara, Nishishirakawa (JP); Suguru Matsumoto, Nishishirakawa (JP); Toshiro Shimada, Nishishirakawa (JP); Ryoji Hoshi, Nishishirakawa (JP)

(72) Inventors: Kosei Sugawara, Nishishirakawa (JP); Suguru Matsumoto, Nishishirakawa (JP); Toshiro Shimada, Nishishirakawa (JP); Ryoji Hoshi, Nishishirakawa (JP)

(73) Assignee: SHIN-ETSU HANDOTAI CO., LTD., Tokyo (JP)

(21) Appl. No.: 13/990,266

(22) PCT Filed: Jan. 6, 2012
(86) PCT No.: PCT/JP2012/000050

§ 371 Date: May 29, 2013

(30) Foreign Application Priority Data
Jan. 19, 2011 (JP) 2011-008433

(51) Int. Cl. C30B 15/14

(52) U.S. Cl. CPC C30B 15/14
USPC 117/13; 117/217

(57) ABSTRACT

A single crystal production apparatus including: a crucible containing raw material melt; a heater heating the raw material melt; a cooling cylinder that is cooled forcedly by a cooling medium; and a cooling chamber that houses the crucible, the heater, and the cooling cylinder, wherein a heat-shielding member having a heat insulating material is disposed, near an interface between the raw material melt and a single crystal being pulled, in such a way as to surround the single crystal being pulled, the cooling cylinder is disposed above the heat-shielding member in such a way as to surround the single crystal being pulled, and a cooling-cylinder-peripheral heat insulator is disposed with a gap provided between the cooling-cylinder-peripheral heat insulator and a periphery of the cooling cylinder in such a way as to surround the cooling cylinder.

### TECHNICAL FIELD

The present invention relates to a single crystal production apparatus and a method for producing a single crystal, the apparatus and the method that perform crystal cooling, when a single crystal is pulled from raw material melt in a crucible by the Czochralski method, by providing a heat-shielding member immediately above a raw material melt surface and using a cooling cylinder.

### BACKGROUND ART

As a method for producing a silicon single crystal used in production of a semiconductor device, the Czochralski method (also called the CZ method) by which a silicon single crystal is grown and pulled from raw material melt in a quartz crucible has been widely implemented. In the CZ method, a silicon single crystal having a desired diameter is grown by immersing a seed crystal in raw material melt (silicon melt) in a quartz crucible in an atmosphere of inert gas and pulling the seed crystal while rotating the quartz crucible and the seed crystal.

In recent years, as the semiconductor devices become higher integrated and the semiconductor devices become accordingly finer, a growth defect (also called a grown-in defect) in a silicon wafer has become a problem. The growth defect becomes a factor for degrading the characteristics of the semiconductor device, and, as the device becomes increasingly fine, the effect of the growth defect is further increased. As such a growth defect, for example, an octahedral void-shaped defect which is an agglomeration of vacancies in a silicon single crystal produced by the CZ method (Nonpatent Literature 1), a dislocation cluster formed as an agglomeration of interstitial silicon (Nonpatent Literature 2), and the like are known.

It has been revealed that the introduction amount of these growth defects is determined by the temperature gradient of a crystal in an interface region between a solid phase and a liquid phase of a silicon single crystal and the growth rate of the silicon single crystal (Nonpatent Literature 3). As for a method for producing a low-defect silicon single crystal using this fact, for example, slowing the growth rate of a silicon single crystal (Patent Literature 1) and pulling a silicon single crystal at a rate that does not exceed the maximum pulling rate which is roughly proportional to the temperature gradient in an interface region of a silicon single crystal (Patent Literature 2) have been disclosed.

Furthermore, an improved CZ method focused on the temperature gradient (G) and the growth rate (V) during growth of a crystal (Nonpatent Literature 4), for example, has been reported, and it is necessary to cool a crystal rapidly to increase a crystal temperature gradient to obtain a high-quality silicon single crystal of a defect-free region at a high growth rate.

Moreover, a single crystal production apparatus provided with a cooling cylinder and a cooling support member extending downward from the cooling cylinder and having a cylindrical shape or a shape whose diameter is reduced downward, the single crystal production apparatus having a heat-shielding member in the cooling support member extending from the cooling cylinder, is disclosed (Patent Literature 3). However, since the heat is supplied to the side where a crystal is located from an external high-temperature region through a portion in which the heat-shielding member is not provided, cooling capacity for cooling a single crystal which is being grown is inadequate.

Furthermore, a single crystal production apparatus that can suppress a twin crystal or dislocation caused by solid-phase SiO generated as a result of a SiO component in the gas phase being cooled and solidified around the outer perimeter of a cooling cylinder when the cooling cylinder is used by using an inner periphery of the cooling cylinder as a radiant heat reflection prevention surface and a portion facing melt as a radiant heat reflection surface and providing an insulating element on an outer periphery is disclosed (Patent Literature 4).

However, since insulation is provided only by placing the insulating element on the outer periphery of the cooling cylinder in such a way that the insulating element is brought into intimate contact with the outer periphery of the cooling cylinder, forced cooling capacity depends on the inner periphery of the cooling cylinder. To achieve further improvement of the cooling capacity, there is only the following option: placing the cooling cylinder in the vicinity, having higher-temperature, of a solid-liquid interface or improving surface emissivity to promote absorption of heat. However, the former causes generation of solidification on a melt surface, the generation of solidification caused as a result of the melt surface also being cooled, and generation of dislocation due to an increase in the number of occurrences of adhesion of foreign matter, the increase caused by a quartz crucible piece generated from a quartz crucible which is a holder of raw material melt, and it is difficult for the latter to contribute to further rapid cooling because the upper limit of the surface emissivity is 1.

Moreover, a semiconductor single crystal production apparatus in which at least part of the outer periphery of a cooling cylinder is covered with a heat reflecting layer is disclosed (Patent Literature 5). However, as is the case with Patent Literature 4 described above, since forced cooling capacity depends on the inner periphery of the cooling cylinder, this apparatus has problems similar to the above-mentioned problems.

### CITATION LIST

### Patent Literature

Patent Literature 1: Japanese Unexamined Patent publication (Kokai) No. H6-56588

Patent Literature 2: Japanese Unexamined Patent publication (Kokai) No. H7-257991

Patent Literature 3: WO01/057293

Patent Literature 4: Japanese Examined Patent publication (Koukoku) No. H7-33307

Patent Literature 5: WO02/103092

Nonpatent Literature 1: Analysis of side-wall structure of grown-in twin-type octahedral defects in Czochralski silicon, Jpn. J. Appl. Phys. Vol. 37 (1998) p-p. 1667-1670

Nonpatent Literature 2: Evaluation of microdefects in as-grown silicon crystals, Mat. Res. Soc. Symp. Proc. Vol. 262 (1992) p-p. 51-56

Nonpatent Literature 3: The mechanism of swirl defects formation in silicon, Journal of Crystal growth 1982 p-p. 625-643

Nonpatent Literature 4: Journal of the Japanese Association for Crystal Growth vol. 25 No. 5 1998

### SUMMARY OF THE INVENTION

### Problems to be Solved by the Invention

The present invention has been made in view of these problems and an object thereof is to provide a single crystal production apparatus and a method for producing a single crystal, the apparatus and the method that can improve the productivity and the yield of single crystal production and reduce power consumption by improving the cooling capacity of a cooling cylinder without generation of solidification on a melt surface and generation of dislocation and by increasing the pulling rate at the time of production of a defect-free single crystal.

### Means for Solving the Problems

To solve the above-described problems, the present invention provides a single crystal production apparatus including: a crucible containing raw material melt; a heater heating the raw material melt; a cooling cylinder that is cooled forcedly by a cooling medium; and a cooling chamber that houses the crucible, the heater, and the cooling cylinder, wherein a heat-shielding member is disposed, near an interface between the raw material melt and a single crystal being pulled, in such a way as to surround the single crystal being pulled, the cooling cylinder is disposed above the heat-shielding member in such a way as to surround the single crystal being pulled, and a cooling-cylinder-peripheral heat insulator is disposed with a gap provided between the cooling-cylinder-peripheral heat insulator and a periphery of the cooling cylinder in such a way as to surround the cooling cylinder.

As described above, with the single crystal production apparatus in which the cooling-cylinder-peripheral heat insulator is disposed with a gap provided between the cooling-cylinder-peripheral heat insulator and the periphery of the cooling cylinder, since the cooling-cylinder-peripheral heat insulator keeps out the heat applied to the gap and the cooling cylinder from the periphery, the space formed by the gap is cooled by the outer perimeter and the bottom end of the cooling cylinder and the temperature thereof is reduced. This makes it possible to make not only the inner perimeter of the cooling cylinder but also the space formed by the gap whose temperature has been reduced contribute to crystal cooling of a single crystal which is being grown.

Moreover, this makes it possible to enhance crystal cooling, and, since there is no need to bring the cooling cylinder close to a high-temperature portion near a melt surface, it is possible to suppress solidification that occurs in an interface between the raw material melt and a single crystal which is being grown and generation of dislocation due to an increase in the number of occurrences of adhesion of foreign matter caused by a quartz crucible piece. Furthermore, this makes it possible to increase the pulling rate of a crystal and thereby improve the productivity and the yield of single crystal production.

In addition, since the load on the cooling cylinder at the time of crystal cooling is reduced as a result of the gap contributing to crystal cooling, it is possible to reduce power consumption of the production apparatus and reduce costs.

Moreover, at this time, it is possible that the gap has a width of 15 mm or more.

With the gap having such a width, when the gap is cooled by the outer perimeter of the cooling cylinder and the temperature of the gap is reduced, it is possible to achieve cooling performance effective for a single crystal which is being grown.

Furthermore, at this time, it is possible that the cooling-cylinder-peripheral heat insulator has a thickness of 20 mm or more, a lower end in a vertical direction which is in a position equal to the level of a bottom end of the heat-shielding member, and an upper end which is located in an area from a position 50 mm above a lower end of the cooling cylinder to an upper inner wall of the cooling chamber.

With such a cooling-cylinder-peripheral heat insulator, it is possible to provide a gap between the cooling-cylinder-peripheral heat insulator and the cooling cylinder reliably and make the heat insulating performance of the cooling-cylinder-peripheral heat insulator more effective. This makes it possible to cool more efficiently a single crystal which is being grown by the gap whose temperature has been reduced.

In addition, at this time, it is possible that the heat-shielding member is cylindrical, has a heat insulating material, and is formed in such a way that the inside diameter thereof increases toward an upper part thereof.

With such a heat-shielding member, it is possible to further enhance crystal cooling by the gap whose temperature has been reduced while suppressing the radiant heat applied, by the raw material melt and the heater, to a single crystal which is being grown.

Moreover, at this time, it is possible that the upper inner wall of the cooling chamber is covered with an upper-wall-heat-insulating material.

By doing so, it is possible to suppress more efficiently the radiant heat applied to the cooling chamber upper inner wall and the cooling cylinder from the high-temperature portion such as the heater. This reduces heater power, making it possible to enhance crystal cooling of a single crystal which is being grown, and at the same time achieve power saving.

Furthermore, at this time, it is possible that a graphite material is disposed in such a way as to be brought into intimate contact with any one of an inner periphery and an outer periphery of the cooling cylinder or both.

With such a cooling cylinder, since the heat absorption performance of the cooling cylinder is enhanced by the graphite material, it is possible to further improve the cooling capacity achieved by the cooling cylinder and the gap whose temperature has been reduced.

In addition, at this time, it is possible that the cooling-cylinder-peripheral heat insulator has a surface covered with a graphite material.

With such a cooling-cylinder-peripheral heat insulator, it is possible to prevent contamination of the raw material melt caused by particle generation from the heat insulating material and generation of dislocation in a grown single crystal.

Moreover, the present invention provides a method for producing a single crystal, the method by which a single crystal is produced by pulling a single crystal from raw material melt by the Czochralski method in a chamber while applying heat to the raw material melt in a crucible with a heater, and by cooling the single crystal being pulled with a cooling cylinder, wherein a single crystal is produced by using the single crystal production apparatus of the present invention.

As described above, with the method for producing a single crystal, the method using the single crystal production apparatus of the present invention, it is possible to produce a single crystal while increasing the pulling rate of the crystal with ease and at the same time suppressing solidification of the raw material melt and generation of dislocation.

### Advantageous Effects of the Invention

As described above, according to the present invention, by disposing a cooling-cylinder-peripheral heat insulator with a gap provided between the cooling-cylinder-peripheral heat insulator and the periphery of a cooling cylinder, since it is possible to make not only the inner perimeter of the cooling cylinder but also the gap whose temperature has been reduced by the outer perimeter of the cooling cylinder contribute to crystal cooling of a single crystal which is being grown, it is possible to increase the pulling rate of a crystal while suppressing generation of solidification on a melt surface and generation of dislocation in the grown single crystal and improve the productivity and the yield of single crystal production.

### BRIEF DESCRIPTION OF THE DRAWINGS

FIG. 1 is a schematic diagram of a cross-section configuration example of a structure around a cooling cylinder of a single crystal production apparatus of the present invention;

FIG. 2 is a diagram of a cross-section configuration example when an upper end of a cooling-cylinder-peripheral heat insulator is brought into intimate contact with a cooling chamber upper inner wall and the cooling chamber upper inner wall is covered with an upper-wall-heat-insulating material in the single crystal production apparatus of the present invention;

FIG. 3 is a diagram of a cross-section configuration example when a graphite material is disposed in such a way as to be brought into intimate contact with the outer periphery of the cooling cylinder in the single crystal production apparatus of the present invention;

FIG. 4 is a diagram of a cross-section configuration example when a heat-shielding member is formed of a heat insulating material and the inside diameter thereof increases toward the upper part thereof in the single crystal production apparatus of the present invention;

FIG. 5 is a diagram of a cross-section configuration example of a single crystal production apparatus provided with an existing cooling cylinder;

FIG. 6 is a diagram of a cross-section configuration example when an upper end of a heat insulating material is brought into intimate contact with a cooling chamber upper inner wall and a side face is brought into intimate contact with the cooling cylinder in a single crystal production apparatus provided with an existing cooling cylinder;

FIG. 7 is a diagram of a cross-section configuration example when a gap is provided between the cooling cylinder and a support for hanging a heat insulating material in a single crystal production apparatus provided with an existing cooling cylinder;

FIG. 8 is a diagram of a graph of the results of the silicon single crystal growth rate at which the wafer entire plane becomes defect-free when Comparative Example 1 is assumed to be 100% in examples and comparative examples;

FIG. 9 is a diagram of a graph of the results of the rate of occurrence of solidification on a melt surface in the examples and the comparative examples;

FIG. 10 is a diagram of a graph of the results of the DF ratio in the examples and the comparative examples;

FIG. 11 is a diagram of a graph of the results of heater power during silicon single crystal growth when Comparative Example 1 is assumed to be 100% in the examples and the comparative examples; and

FIG. 12 is a diagram of a graph of the results of the amount of heat removed from the cooling cylinder when Comparative Example 1 is assumed to be 100% in the examples and the comparative examples.

### BEST MODE FOR CARRYING OUT THE INVENTION

Hereinafter, the present invention will be described more specifically.

As described earlier, to obtain a high-quality silicon single crystal with a defect-free region at a high growth rate, it is necessary to cool a crystal rapidly to increase a crystal temperature gradient.

On the other hand, in the past, a technique of performing forced cooling by using a cooling cylinder has been disclosed. Since forced cooling capacity depends on the inner periphery of the cooling cylinder, to achieve further improvement of cooling capacity, it is necessary to place the cooling cylinder in the vicinity, having higher-temperature, of a solid-liquid interface, for example. However, this causes generation of solidification on a melt surface, the generation of solidification caused as a result of raw material melt also being cooled with a single crystal, and generation of dislocation due to an increase in the number of occurrences of adhesion of foreign matter generated from a quartz crucible which is a holder of the raw material melt.

Thus, through an intensive study, the inventors of the present invention have found out that, by forming an internal space which is heat-insulated from the outside by placing a cooling-cylinder-peripheral heat insulator with a gap provided around the outer perimeter of a cooling cylinder, it is possible to obtain a cooled internal space which is cooled by the outer perimeter and a bottom end of the cooling cylinder, and the cooled internal space contributes to crystal cooling with the inner perimeter and the bottom end of the cooling cylinder, making it possible to enhance crystal cooling while suppressing solidification of raw material melt and generation of dislocation in a grown single crystal.

That is, the present invention is a single crystal production apparatus that includes at least a crucible containing raw material melt, a heater heating the raw material melt, a cooling cylinder that is cooled forcedly by a cooling medium, and a cooling chamber that houses them, the single crystal production apparatus in which a heat-shielding member having a heat insulating material is disposed, near an interface between the raw material melt and a single crystal being pulled, in such a way as to surround the single crystal being pulled, the cooling cylinder is disposed above the heat-shielding member in such a way as to surround the single crystal being pulled, and a cooling-cylinder-peripheral heat insulator is disposed with a gap provided between the cooling-cylinder-peripheral heat insulator and a periphery of the cooling cylinder in such a way as to surround the cooling cylinder.

In other words, in the single crystal production apparatus of the present invention, the cooling cylinder is disposed in such a way as to surround a single crystal being pulled, the cooling-cylinder-peripheral heat insulator is disposed with a gap provided between the cooling-cylinder-peripheral heat insulator and the periphery of the cooling cylinder in such a way as to surround the cooling cylinder, and the heat-shielding member is disposed, near an interface between the raw material melt and the single crystal being pulled, at a lower end of the cooling-cylinder-peripheral heat insulator, in such a way as to surround the single crystal being pulled.

Hereinafter, an embodiment of the present invention will be described specifically by taking up production of a silicon single crystal as an example with reference to the drawings, but the present invention is not limited thereto.

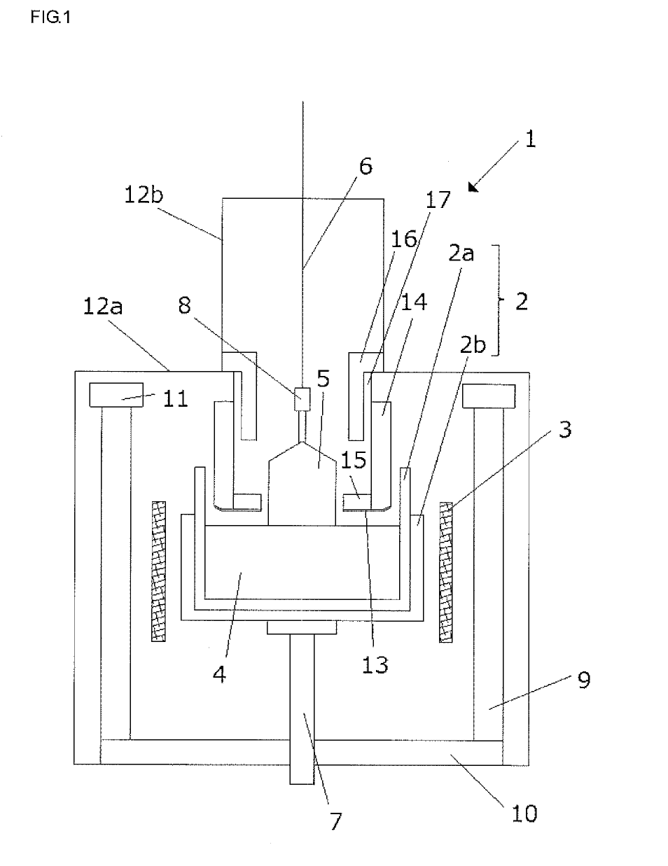

First, in FIG. 1, a schematic diagram of a cross-section configuration example of a structure around a cooling cylinder of the single crystal production apparatus of the present invention is depicted. A single crystal production apparatus 1 of the present invention has an appearance formed as a hollow cylindrical chamber, and the chamber is formed of a cooling chamber 12a forming a lower cylinder and a pull chamber 12b forming an upper cylinder coupled and fixed to the cooling chamber 12a.

At the center thereof, a crucible 2 is disposed, and the crucible has a double structure and is formed of a quartz inner holder (hereinafter simply referred to as a “quartz crucible 2a”) having the shape of a closed-end cylinder and a graphite outer holder (hereinafter simply referred to as a “graphite crucible 2b”) also having the shape of a closed-end cylinder, the graphite outer holder adjusted to hold the outside of the quartz crucible 2a.

On the outside of the crucible 2 having the double structure, a heater 3 is disposed, around the outside of the heater 3, a thermal insulating cylinder 9 is disposed concentrically, below the thermal insulating cylinder 9 and at the bottom of the apparatus, a thermal insulating plate 10 is disposed, and, above the thermal insulating cylinder 9, a thermal insulating member 11 is disposed.

A silicon raw material of a predetermined weight that is charged into the crucible 2 is melted, and raw material melt 4 is formed. A seed crystal 8 is immersed in the surface of the raw material melt 4 thus formed, the crucible 2 is rotated by a support shaft 7, and a silicon single crystal 5 is grown on a lower end surface of the seed crystal 8 by pulling a pulling shaft 6 upward while rotating the pulling shaft 6 in a direction opposite to the direction in which the crucible 2 is rotated.

Here, near an interface between the raw material melt 4 and the single crystal 5, a heat-shielding member 15 having a heat insulating material is disposed in such a way as to surround the single crystal 5. This heat-shielding member 15 makes it possible to suppress radiant heat applied to the single crystal 5 which is being grown from the raw material melt 4. As the material of the heat-shielding member 15, for example, graphite, molybdenum, tungsten, silicon carbide, graphite whose surface is coated with silicon carbide, or the like can be used. However, the material is not limited thereto.

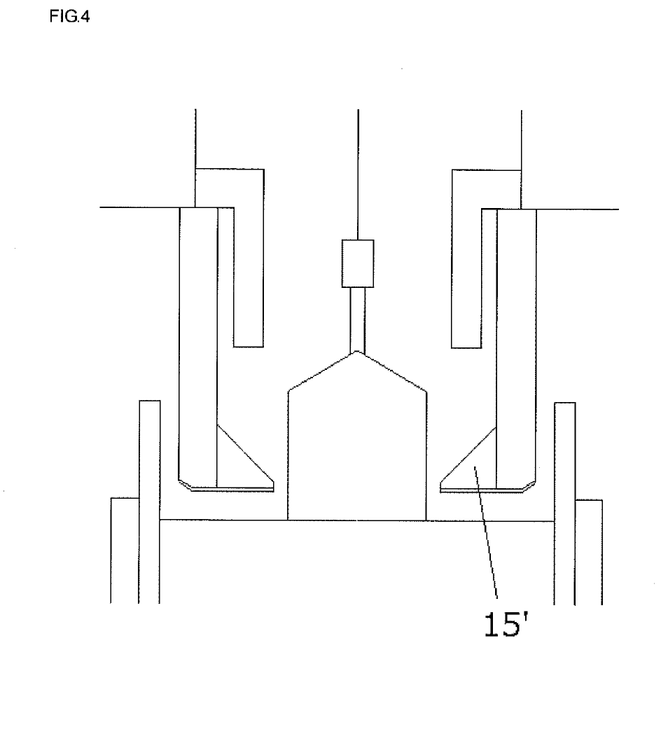

Furthermore, when the heat-shielding member is formed into a cylindrical shape and is formed as a heat-shielding member 15′ formed of a heat insulating material, the heat-shielding member 15′ whose inside diameter increases toward the upper part thereof as depicted in FIG. 4, it is possible to further enhance crystal cooling by the gap whose temperature has been reduced while suppressing the radiant heat.

Moreover, the cooling cylinder 16 that is disposed on the periphery of the single crystal 5 above the heat-shielding member 15 in such a way as to surround the single crystal 5 being pulled is cooled at about 10 to 50° C. by using water as a cooling medium, and performs forced cooling of the single crystal 5 mainly by radiant heat transfer. As the material of the cooling cylinder 16, for example, iron, nickel, chromium, copper, titanium, molybdenum, tungsten, an alloy containing these metals, or these alloys coated with titanium, molybdenum, tungsten, or platinum metal can be used. However, the material is not limited thereto.

In addition, in the present invention, a cooling-cylinder-peripheral heat insulator 14 is disposed above a heat insulating plate 13 in such a way as to surround the cooling cylinder 16 with a gap 17, whereby the radiant heat applied to the single crystal 5 from the heater 3 is alleviated and kept out. As the material of the cooling-cylinder-peripheral heat insulator 14, for example, such a carbon fiber molded body can be used. However, the material is not limited thereto.

Here, the gap 17 is formed to have preferably a width of 15 mm or more and more preferably a width of 20 mm or more but 50 mm or less.

Since the space formed by this gap 17 is cooled by the outer perimeter of the cooling cylinder 16 and the temperature thereof is reduced, it is possible to make, in addition to the inner perimeter of the cooling cylinder 16, the space formed by the gap 17 whose temperature has been reduced contributes to crystal cooling. Furthermore, since the periphery is surrounded with the cooling-cylinder-peripheral heat insulator 14, it is possible to intercept the flow of heat from the periphery into the gap 17 reliably. This makes it possible to further enhance crystal cooling.

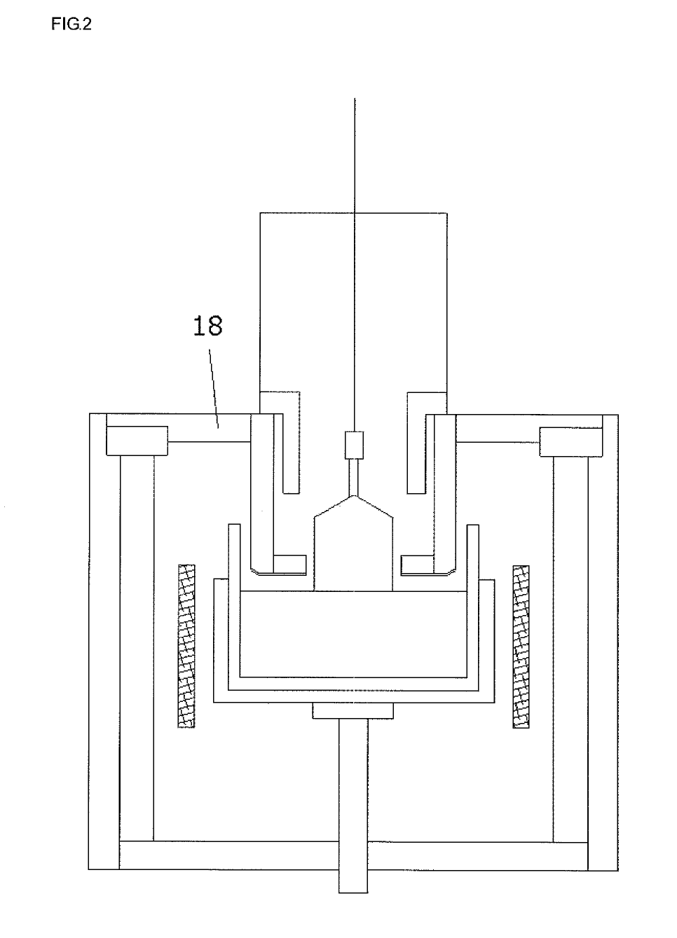

Moreover, the cooling-cylinder-peripheral heat insulator 14 is formed to have preferably a thickness of 20 mm or more and more preferably a thickness of 25 mm or more but 100 mm or less. Furthermore, a lower end in a vertical direction is located in a position equal to the level of the bottom end of the heat-shielding member 15, and an upper end is formed to be located in an area from a position preferably 50 mm and more preferably 150 mm above the lower end of the cooling cylinder 16 to an upper inner wall of the cooling chamber 12a. In addition, as depicted in FIG. 2, it is more preferable that the cooling-cylinder-peripheral heat insulator 14 is formed in such a way that the smallest possible gap is formed between the upper end thereof and the upper inner wall of the cooling chamber 12a.

This makes it possible to improve the heat insulating effect of the cooling-cylinder-peripheral heat insulator 14 and make the crystal cooling performance thereof more effective when the temperature of the gap 17 is reduced.

Furthermore, by covering the upper inner wall of the cooling chamber 12a with an upper-wall-heat-insulating material 18 as depicted in FIG. 2, it is possible to intercept more efficiently the radiant heat applied to the upper inner wall of the cooling chamber 12a from a high-temperature portion such as the heater 3 and the radiant heat that reaches the gap 17 through the side wall of the cooling-cylinder-peripheral heat insulator 14 from the high-temperature portion such as the heater 3 and thereby it is possible to suppress the radiant heat applied to the single crystal 5 more efficiently, and at the same time to achieve power saving by a reduction of heater power.

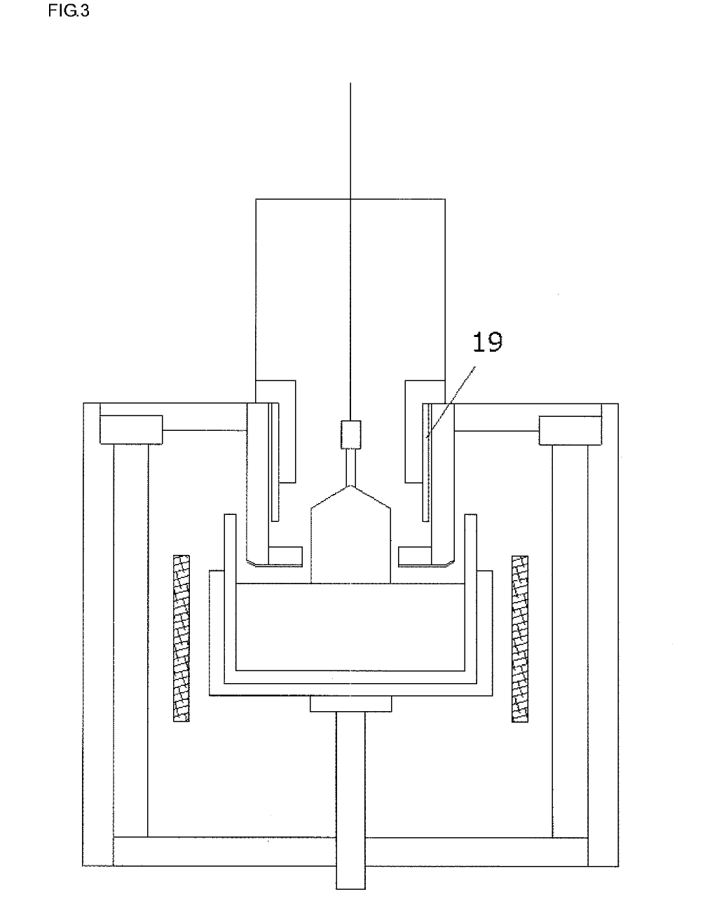

In addition, as depicted in FIG. 3, it is possible to place a graphite material 19 in such a way as to be brought into intimate contact with the outer periphery of the cooling cylinder 16 which is subjected to forced cooling. By placing the graphite material 19 which is a high thermal conductor in such a way as to be brought into intimate contact with the outer periphery of the cooling cylinder 16 in this manner, cooling of the gap 17 is further promoted, making it possible to enhance crystal cooling. At this time, the graphite material may be disposed in such a way as to be brought into intimate contact with not only the outer periphery of the cooling cylinder but also the inner periphery of the cooling cylinder or both of the outer and inner peripheries of the cooling cylinder.

In a method for producing a single crystal of the present invention, a single crystal is produced in the following manner by using the above-described apparatus.

First, the seed crystal 8 is immersed in the raw material melt 4 held by the crucible 2. Then, the seed crystal 8 is pulled while being rotated by the pulling shaft 6. At this time, heating is performed by the heater 3, and the crucible 2 is rotated by the support shaft 7 in a direction opposite to the direction in which the seed crystal 8 is rotated. Then, the pulled single crystal 5 is cooled rapidly by the cooling cylinder 16, whereby the single crystal 5 is produced.

At this time, since the cooling-cylinder-peripheral heat insulator 14 is disposed on the periphery of the cooling cylinder 16 with the gap 17 provided therebetween, it is possible to intercept reliably the radiant heat applied to the gap 17 from the high-temperature portion such as the heater 3. As a result, since the space formed by the gap 17 is cooled by the outer perimeter and the bottom end of the cooling cylinder 16 and the temperature thereof is reduced, it is possible to make the space whose temperature has been reduced contribute to crystal cooling and enhance crystal cooling.

Moreover, this makes it possible to suppress solidification generated on the melt surface and generation of dislocation. Furthermore, this makes it possible to increase the pulling rate of the crystal and improve the productivity and the yield of single crystal production.

### EXAMPLES

Hereinafter, the present invention will be described more specifically by examples and comparative examples, but the present invention is not limited to these examples.

### Example 1

In the single crystal production apparatus depicted in FIG. 1, a gap of 60 mm was provided between a cooling cylinder and a cooling-cylinder-peripheral heat insulator having a thickness of 30 mm, the lower end of a cooling-cylinder-peripheral heat insulator was located in a position equal to the bottom end of a heat-shielding member, and the upper end was located 150 mm above the lower end of the cooling cylinder. By using such a production apparatus, a quartz crucible having an inside diameter of 800 mm was filled with 200 kg of silicon raw material, raw material melt was formed, a silicon single crystal having a diameter of 300 mm was then pulled and grown, and the silicon single crystal growth rate at which the wafer entire plane became defect-free, the rate of occurrence of solidification on the melt surface, the DF ratio (the probability that a single crystal with no dislocation throughout the length of the crystal is obtained), heater power during silicon single crystal growth, and the amount of heat removed from the cooling cylinder were determined. Incidentally, the amount of heat removed from the cooling cylinder was determined based on the quantity and the amount of increase in temperature of water used for cooling, and, by dividing a cooling water channel into a plurality of channels and disposing these channels, it was possible to measure the overall amount of removed heat and the amount of heat removed from the outer perimeter separately.

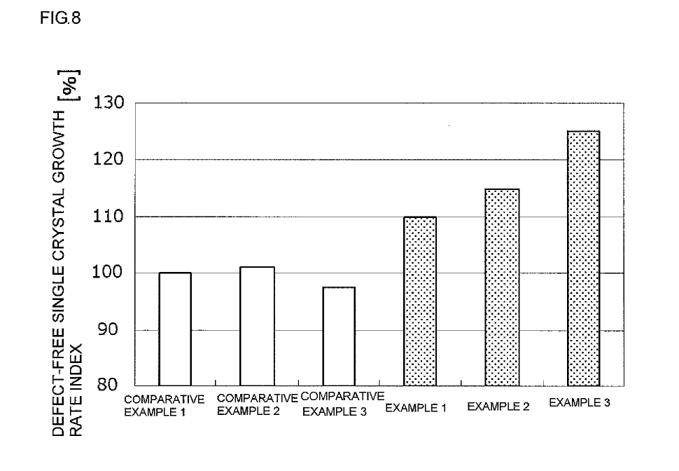

The results thus obtained are shown in FIGS. 8 to 12.

### Example 2

In the single crystal production apparatus depicted in FIG. 2, the silicon single crystal growth rate at which the wafer entire plane became defect-free, the rate of occurrence of solidification on the melt surface, the DF ratio, heater power during silicon single crystal growth, and the amount of heat removed from the cooling cylinder were determined in the same manner as in Example 1 except that the upper end of the cooling-cylinder-peripheral heat insulator was brought into intimate contact with the cooling chamber upper inner wall and the cooling chamber upper inner wall was covered with the upper-wall-heat-insulating material.

The results thus obtained are shown in FIGS. 8 to 12.

### Example 3

In the single crystal production apparatus depicted in FIG. 3, the silicon single crystal growth rate at which the wafer entire plane became defect-free, the rate of occurrence of solidification on the melt surface, the DF ratio, heater power during silicon single crystal growth, and the amount of heat removed from the cooling cylinder were determined in the same manner as in Example 2 except that the heat-shielding member formed of a heat insulating material was formed in such a way that the inside diameter thereof increases toward the upper part thereof as depicted in FIG. 4 and the graphite material was disposed in such a way as to be brought into intimate contact with the outer periphery of the cooling cylinder. The results thus obtained are shown in FIGS. 8 to 12.

### Comparative Example 1

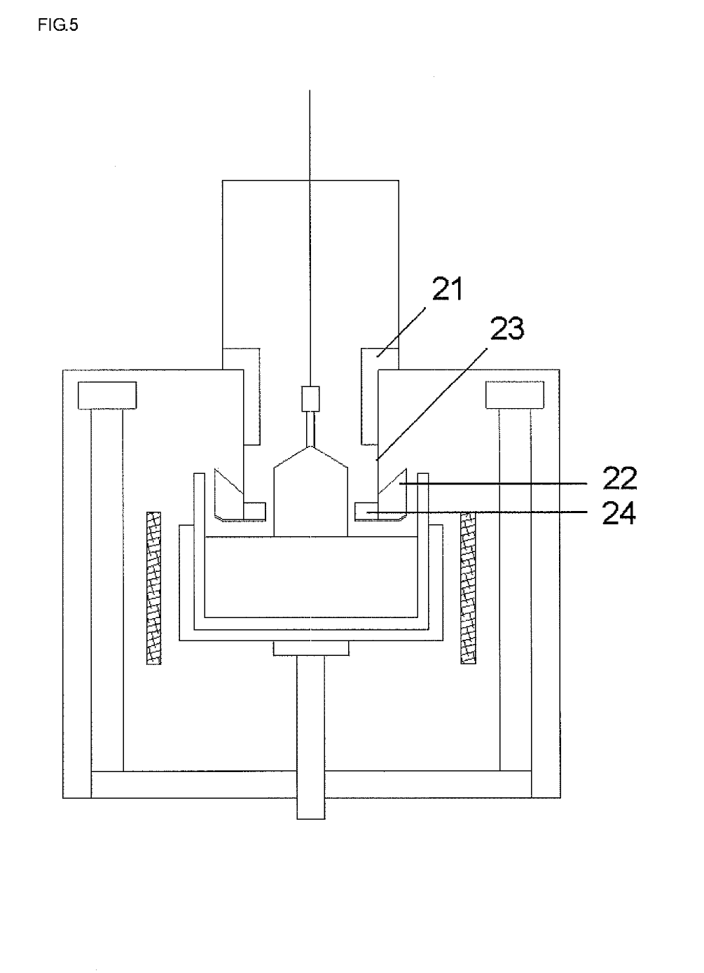

In a single crystal production apparatus depicted in FIG. 5, a cooling cylinder 21 and a heat insulating material 22 having a thickness of 30 mm, the heat insulating material 22 surrounding a single crystal which was being grown, were provided, and a gap was not provided between the cooling cylinder 21 and a support 23 for hanging the heat insulating material 22. The lower end of the heat insulating material 22 was located in a position equal to the bottom end of a heat-shielding member 24, and the upper end was located 150 mm below the bottom end of the cooling cylinder 21. By using such a production apparatus, a quartz crucible having an inside diameter of 800 mm was filled with 200 kg of silicon raw material, raw material melt was formed, a silicon single crystal having a diameter of 300 mm was then pulled and grown, and the silicon single crystal growth rate at which the wafer entire plane became defect-free, the rate of occurrence of solidification on the melt surface, the DF ratio, heater power during silicon single crystal growth, and the amount of heat removed from the cooling cylinder were determined. The results thus obtained are shown in FIGS. 8 to 12.

### Comparative Example 2

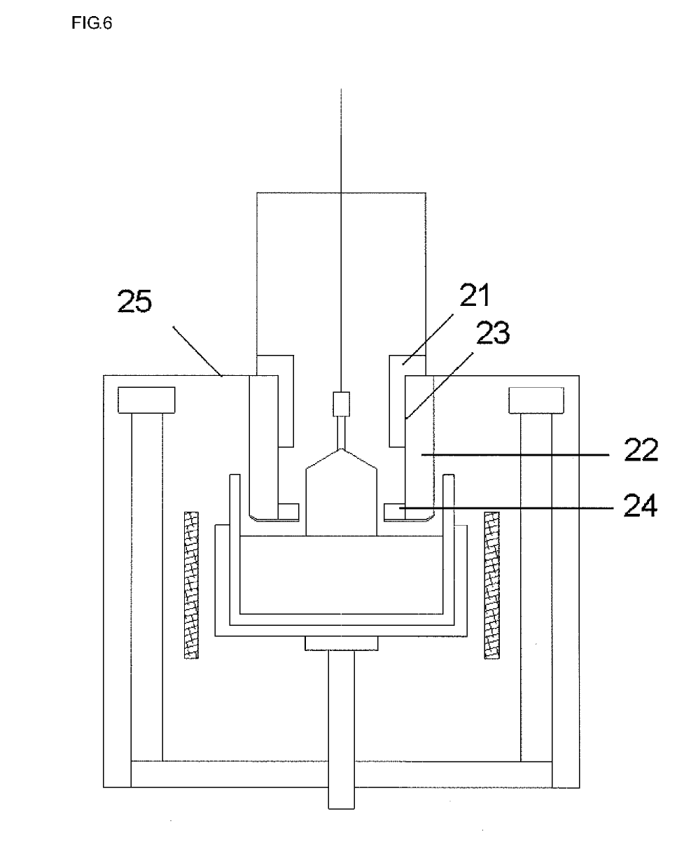

In a single crystal production apparatus depicted in FIG. 6, the silicon single crystal growth rate at which the wafer entire plane became defect-free, the rate of occurrence of solidification on the melt surface, the DF ratio, heater power during silicon single crystal growth, and the amount of heat removed from the cooling cylinder were determined under the same condition as that of Comparative Example 1 except that the upper end of a heat insulating material 22 was brought into intimate contact with an upper inner wall of a cooling chamber 25 and the side face was brought into intimate contact with a cooling cylinder 21. The results thus obtained are shown in FIGS. 8 to 12.

### Comparative Example 3

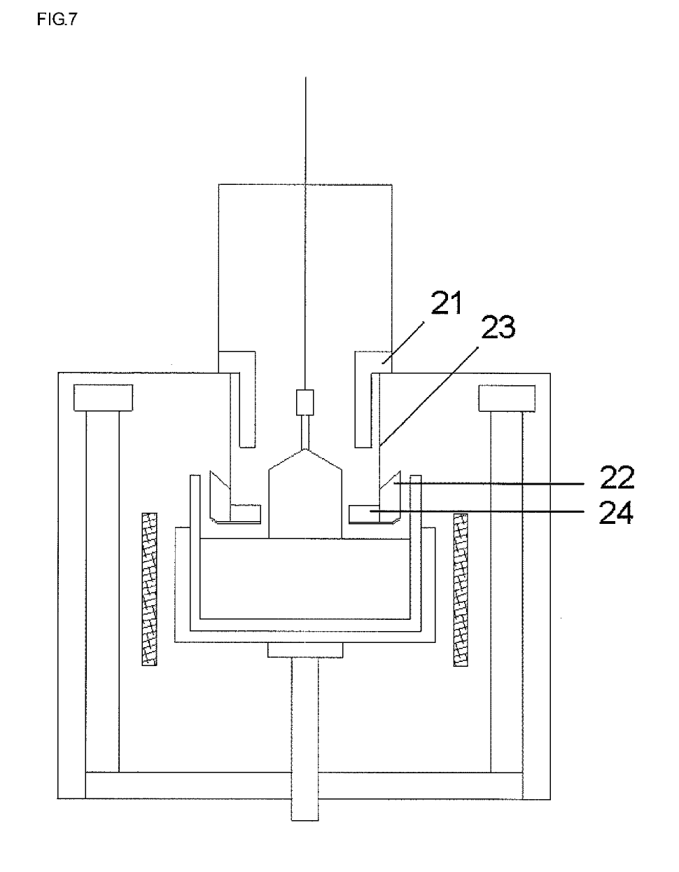

In a single crystal production apparatus depicted in FIG. 7, the silicon single crystal growth rate at which the wafer entire plane became defect-free, the rate of occurrence of solidification on the melt surface, the DF ratio, heater power during silicon single crystal growth, and the amount of heat removed from the cooling cylinder were determined under the same condition as that of Comparative Example 1 except that a gap having a width of 60 mm was provided between a cooling cylinder 21 and a support 23 for hanging a heat insulating material 22. The results thus obtained are shown in FIGS. 8 to 12.

FIG. 8 is a diagram of a graph of the results of the silicon single crystal growth rate at which the wafer entire plane becomes defect-free when Comparative Example 1 is assumed to be 100% in the examples and the comparative examples. In FIG. 8, it is revealed that, in the examples of the present invention, as compared to Comparative Example 1, the defect-free silicon single crystal growth rates are increased by 10 to 25%. This is because, by providing insulation by providing a gap between the outer perimeter of the cooling cylinder and the cooling-cylinder-peripheral heat insulator, the space formed by the gap is cooled and the temperature thereof is reduced, which contributes to crystal cooling and makes it possible to enhance crystal cooling.

On the other hand, in Comparative Example 2 in which the outer perimeter of the cooling cylinder and the heat insulating material are brought into intimate contact with each other and a gap is not provided therebetween and Comparative Example 3 in which, even when a gap is provided, insulation by the heat insulating material is not adequately provided because the upper end of the heat insulating material is located below the bottom end of the cooling cylinder, the defect-free silicon single crystal growth rate can hardly be increased.

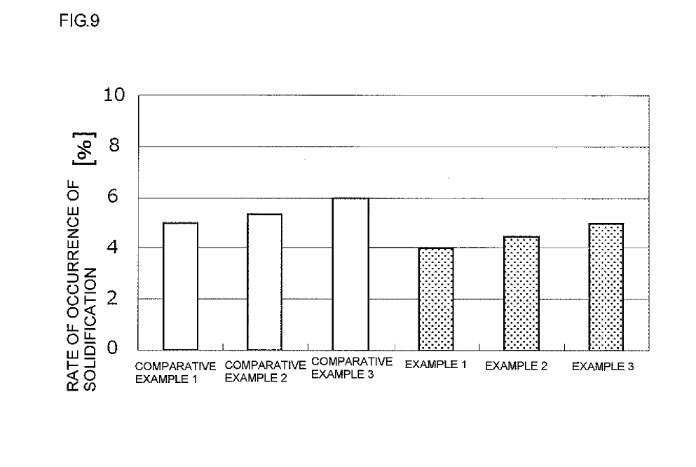

In FIG. 9, it is revealed that, in the examples of the present invention, since there is no need to bring the cooling cylinder close to the high-temperature portion near the melt interface, the rate of occurrence of solidification is not deteriorated in spite of an increase in the defect-free silicon single crystal growth rate by the above-described enhancement of cooling and, if anything, the rate of occurrence of solidification is reduced.

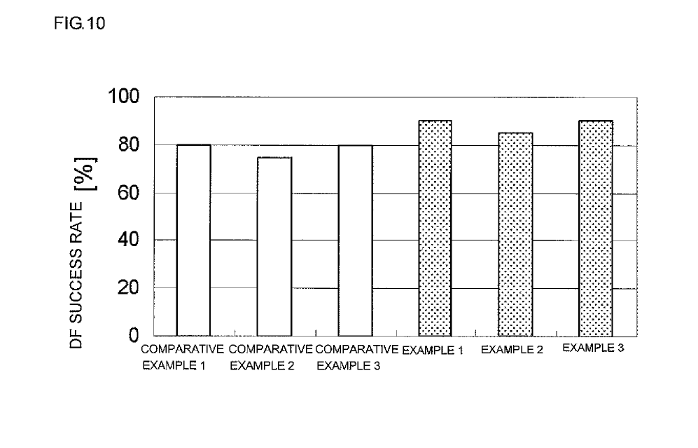

In FIG. 10, in the examples of the present invention, the defect-free silicon single crystal growth rate can be increased and the DF ratio is also somewhat increased as compared to the comparative examples.

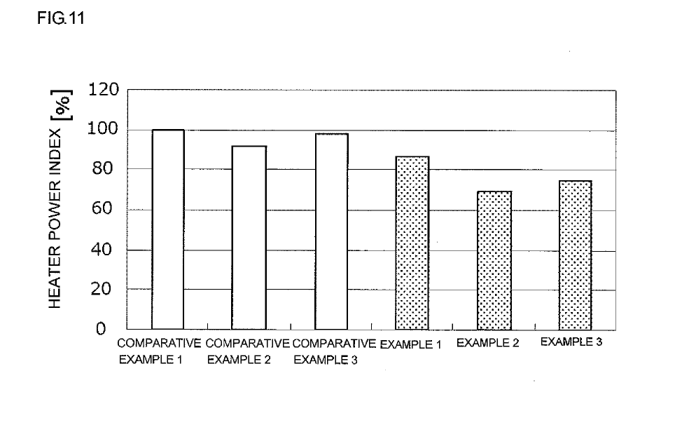

FIG. 11 is a diagram of a graph of the results of heater power during silicon single crystal growth when Comparative Example 1 is assumed to be 100% in the examples and comparative examples. In FIG. 11, in Example 1 of the present invention, since the gap between the cooling cylinder and the cooling-cylinder-peripheral heat insulator is heat-insulated from the external high-temperature portion, as compared to Comparative Example 1, a power saving of 12% is achieved. Moreover, in Example 2 and Example 3, since a heat insulating structure is adopted in which the upper end of the heat insulating material of the outer perimeter of the cooling cylinder is brought into intimate contact with the upper inner wall of the cooling chamber and the cooling chamber heat insulating material is used, as compared to Comparative Example 1, a power saving of 25 to 31% is achieved.

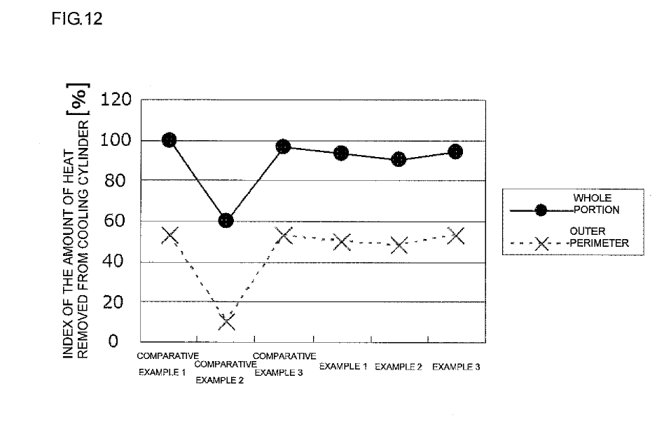

FIG. 12 is a diagram of a graph of the results of the amount of heat removed from the cooling cylinder when Comparative Example 1 is assumed to be 100% in the examples and the comparative examples. In FIG. 12, in the examples of the present invention, there is little difference between the amounts of removed heat irrespective of the fact that the heater power is reduced as compared to the comparative examples as described earlier. This is because the space cooled also by the outer perimeter of the cooling cylinder by the presence of the gap as described earlier efficiently contributes to crystal cooling.

As described above, according to the single crystal production apparatus and the method for producing a single crystal of the present invention, in a single crystal pulling process, by providing insulation from an external high-temperature portion with providing a gap between the outer perimeter of the cooling cylinder and the cooling-cylinder-peripheral heat insulator and by cooling the gap mainly with the outer perimeter of the cooling cylinder, the temperature of the gap is reduced, which makes it possible to enhance crystal cooling.

As a result, since it is possible to increase the crystal growth rate and improve the productivity of defect-free crystal production while maintaining high yield, which makes it possible to obtain a silicon single crystal with great productivity while providing energy savings, the apparatus and the method can be widely used in the manufacturing field of a silicon single crystal for a semiconductor device and a silicon single crystal for a solar battery.

It is to be understood that the present invention is not limited in any way by the embodiment thereof described above. The above embodiment is merely an example, and anything that has substantially the same structure as the technical idea recited in the claims of the present invention and that offers similar workings and benefits falls within the technical scope of the present invention.

1-8. (canceled)

9. A single crystal production apparatus comprising:
a crucible containing raw material melt;
a heater heating the raw material melt;
a cooling cylinder that is cooled forcedly by a cooling medium; and
a cooling chamber that houses the crucible, the heater, and the cooling cylinder,
wherein
a heat-shielding member is disposed, near an interface between the raw material melt and a single crystal being pulled, in such a way as to surround the single crystal being pulled, the cooling cylinder is disposed above the heat-shielding member in such a way as to surround the single crystal being pulled, and a cooling-cylinder-peripheral heat insulator is disposed with a gap provided between the cooling-cylinder-peripheral heat insulator and a periphery of the cooling cylinder in such a way as to surround the cooling cylinder.

10. The single crystal production apparatus according to claim 9, wherein the gap has a width of 15 mm or more.

11. The single crystal production apparatus according to claim 9, wherein
the cooling-cylinder-peripheral heat insulator has a thickness of 20 mm or more, a lower end in a vertical direction which is in a position equal to the level of a bottom end of the heat-shielding member, and an upper end which is located in an area from a position 50 mm above a lower end of the cooling cylinder to an upper inner wall of the cooling chamber.

12. The single crystal production apparatus according to claim 10, wherein
the cooling-cylinder-peripheral heat insulator has a thickness of 20 mm or more, a lower end in a vertical direction which is in a position equal to the level of a bottom end of the heat-shielding member, and an upper end which is located in an area from a position 50 mm above a lower end of the cooling cylinder to an upper inner wall of the cooling chamber.

13. The single crystal production apparatus according to claim 9, wherein
the heat-shielding member is cylindrical, has a heat insulating material, and is formed in such a way that the inside diameter thereof increases toward an upper part thereof.

14. The single crystal production apparatus according to claim 10, wherein
the heat-shielding member is cylindrical, has a heat insulating material, and is formed in such a way that the inside diameter thereof increases toward an upper part thereof.

15. The single crystal production apparatus according to claim 11, wherein
the heat-shielding member is cylindrical, has a heat insulating material, and is formed in such a way that the inside diameter thereof increases toward an upper part thereof.

16. The single crystal production apparatus according to claim 12, wherein
the heat-shielding member is cylindrical, has a heat insulating material, and is formed in such a way that the inside diameter thereof increases toward an upper part thereof.

17. The single crystal production apparatus according to claim 9, wherein
the upper inner wall of the cooling chamber is covered with an upper-wall-heat-insulating material.

18. The single crystal production apparatus according to claim 16, wherein
the upper inner wall of the cooling chamber is covered with an upper-wall-heat-insulating material.

19. The single crystal production apparatus according to claim 9, wherein
a graphite material is disposed in such a way as to be brought into intimate contact with any one of an inner periphery and an outer periphery of the cooling cylinder or both.

20. The single crystal production apparatus according to claim 18, wherein
a graphite material is disposed in such a way as to be brought into intimate contact with any one of an inner periphery and an outer periphery of the cooling cylinder or both.

21. The single crystal production apparatus according to claim 9, wherein
the cooling-cylinder-peripheral heat insulator has a surface covered with a graphite material.

22. The single crystal production apparatus according to claim 20, wherein
the cooling-cylinder-peripheral heat insulator has a surface covered with a graphite material.

23. A method for producing a single crystal, the method by which a single crystal is produced by pulling a single crystal from raw material melt by the Czochralski method in a chamber while applying heat to the raw material melt in a crucible with a heater, and by cooling the single crystal being pulled with a cooling cylinder,
wherein
a single crystal is produced by using the single crystal production apparatus according to claim 9.

24. A method for producing a single crystal, the method by which a single crystal is produced by pulling a single crystal from raw material melt by the Czochralski method in a chamber while applying heat to the raw material melt in a crucible with a heater, and by cooling the single crystal being pulled with a cooling cylinder,
wherein
a single crystal is produced by using the single crystal production apparatus according to claim 22.
